(19) United States
(12) Patent Application Publication
(10) Pub. No.: US 2026/0076221 A1
(43) Pub. Date: Mar. 12, 2026

(54) SEMICONDUCTOR PACKAGE STRUCTURE

(71) Applicant: MEDIATEK INC., Hsinchu City (TW)

(72) Inventors: Chuan-An CHENG, Hsinchu City (TW); Po-Chih YANG, Hsinchu City (TW); Ting-Li YANG, Hsinchu City (TW); Cheng-Lin HUANG, Hsinchu City (TW)

(21) Appl. No.: 19/319,861

(22) Filed: Sep. 5, 2025

Related U.S. Application Data
(60) Provisional application No. 63/693,768, filed on Sep. 12, 2024.

(51) Int. Cl. H01L 23/538; H01L 23/00; H01L 23/498; H01L 25/065

(52) U.S. Cl. CPC H10W 70/60; H10W 70/611; H10W 90/00; H10W 90/724; H10W 90/792

(57) ABSTRACT

A semiconductor package structure is provided. The semiconductor package structure includes a first substrate, a first semiconductor die, and a first memory component. The first semiconductor die is disposed over the first substrate and has a first surface adjacent to the first substrate and a second surface away from the first substrate. The first semiconductor die includes a first bonding layer disposed on the second surface of the first semiconductor die. The first memory component is disposed over the first semiconductor die. The first memory component vertically overlaps the first semiconductor die. The first memory component includes a second bonding layer adjacent to the second surface of the first semiconductor die. The first memory component is coupled to the first semiconductor die through a first connection structure formed by the first bonding layer and the second bonding layer.

### CROSS REFERENCE TO RELATED APPLICATIONS

This application claims the benefit of U.S. provisional application No. 63/693,768, filed Sep. 12, 2024, the entirety of which is incorporated by reference herein.

### TECHNICAL FIELD

The present disclosure relates to a semiconductor package structure, and, in particular, it relates to a co-packaging assembly.

### BACKGROUND

With the growing demand for memory bandwidth in high-performance computing applications, package sizes have continued to increase in order to accommodate additional memory devices and interconnects. However, larger package dimensions introduce several challenges, including increased reliability risks and reduced confidence in assembly yield.

In order to ensure the continued miniaturization and multi-functionality of electronic products and communication devices, it is desired that semiconductor packages be small in size, support multi-pin connection, operate at high speeds, and have high functionality, especially in applications such as artificial intelligence (AI), high-performance computing (HPC), and data centers. This puts pressure on semiconductor package fabricators to integrate multiple dies within a single package, thereby minimizing the track lengths between different semiconductor chips and improving electrical performance.

Die-to-HBM physical interfaces (PHYs) are typically routed through a local silicon interconnect (LSI) or bridge die. Such extended routing paths result in power integrity concerns due to additional resistance, inductance, and parasitic effects. Moreover, the LSI or bridge die itself is susceptible to mechanical breakage, thereby raising the risk of failure during operation or handling. Moreover, the increase in package size contributes to higher mechanical stress, such as peel stress, which may adversely affect long-term package reliability.

Accordingly, there is a need for an improved semiconductor package structure capable of providing higher memory bandwidth and storage while maintaining power integrity, and overall reliability.

### BRIEF SUMMARY

In accordance with some embodiments of the present disclosure, a semiconductor package structure is provided. The semiconductor package structure includes a first substrate, a first semiconductor die, and a first memory component. The first semiconductor die is disposed over the first substrate and has a first surface adjacent to the first substrate and a second surface away from the first substrate. The first semiconductor die includes a first bonding layer disposed on the second surface of the first semiconductor die. The first memory component is disposed over the first semiconductor die. The first memory component vertically overlaps the first semiconductor die. The first memory component includes a second bonding layer adjacent to the second surface of the first semiconductor die. The first memory component is coupled to the first semiconductor die through a first connection structure formed by the first bonding layer and the second bonding layer.

In accordance with some embodiments of the present disclosure, a semiconductor package structure is provided. The semiconductor package structure includes a first substrate, a first semiconductor die, and a first memory component. The first semiconductor die is disposed over the first substrate and has a first surface adjacent to the first substrate and a second surface away from the first substrate. The first memory component includes a memory die vertically overlapping the first semiconductor die. The first semiconductor die includes first circuitry configured to control access to the first memory component.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an exemplary semiconductor package structure in accordance with some embodiments of the present disclosure;

FIG. 2 is an enlarged diagram of area R1 in FIG. 1 in accordance with some embodiments of the present disclosure;

FIG. 3 is an enlarged diagram of area R1 in FIG. 1 in accordance with some embodiments of the present disclosure;

FIG. 4 is a cross-sectional diagram of an exemplary semiconductor package structure in accordance with some embodiments of the present disclosure;

FIG. 5 is an enlarged diagram of area R2 in FIG. 4 in accordance with some embodiments of the present disclosure;

FIG. 6 is an enlarged diagram of area R2 in FIG. 4 in accordance with some embodiments of the present disclosure;

FIG. 7 is a cross-sectional diagram of an exemplary semiconductor package structure in accordance with some embodiments of the present disclosure;

FIG. 8 is an enlarged diagram of area R3 in FIG. 7 in accordance with some embodiments of the present disclosure;

FIG. 9 is an enlarged diagram of area R3 in FIG. 7 in accordance with some embodiments of the present disclosure;

FIG. 10 is a cross-sectional diagram of an exemplary semiconductor package structure in accordance with some embodiments of the present disclosure;

FIG. 11 is an enlarged diagram of area R4 in FIG. 10 in accordance with some embodiments of the present disclosure;

FIG. 12 is an enlarged diagram of area R4 in FIG. 10 in accordance with some embodiments of the present disclosure;

FIG. 13 is a chiplet platform architecture diagram of an exemplary semiconductor package structure in accordance with some embodiments of the present disclosure.

### DETAILED DESCRIPTION

The semiconductor package structure according to the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may be understood by referring to the second element in the claims.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “between the first value and the second value” means that the range includes the first value, the second value, and other values in between.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

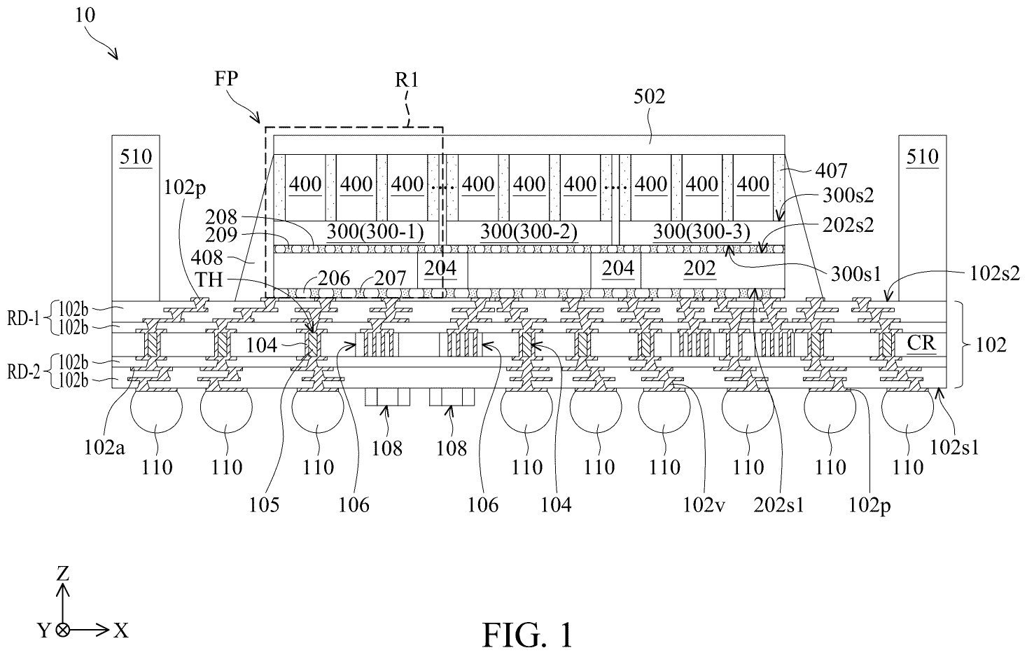

Please refer to FIG. 1, which is a cross-sectional diagram of an exemplary semiconductor package structure 10 in accordance with some embodiments of the present disclosure. It should be understood that some elements of the semiconductor package structure 10 may be omitted in the figure for clarity, and only some elements are schematically illustrated. In accordance with some embodiments, additional features may be added to the semiconductor package structure 10 described below. In accordance with some other embodiments, some features of the semiconductor package structure 10 described below may be replaced or omitted.

The semiconductor package structure 10 can be used to form a package requiring high-power operation, such as flip chip ball grid array (FCBGA), land grid array (LGA), a fan-out semiconductor package, a two-dimensional (2D) semiconductor package, a 2.5D semiconductor package, a three-dimensional (3D) semiconductor package, a 3.5D semiconductor package, or another suitable package. As shown in FIG. 1, the semiconductor package structure 10 includes a substrate 102, a semiconductor die 300 (including semiconductor dies 300-1, 300-2, and 300-3 in the following figure), and a memory component 400 (including memory components 400-1, 400-2, and 400-3 in the following figure).

As shown in FIG. 1, the substrate 102 may include a multi-layered package substrate. The substrate 102 may provide mechanical support and electrical connections between integrated circuit (IC) chips and conductive bumps attached to the top surface 102s2 and bottom surface 102s1 of the substrate 102. The substrate 102 may have various types including, for example, a core substrate or a coreless substrate. The core substrate includes thin core, thick core (e.g., laminate BT (bismaleimide-triazine resin) or FR-4 type fibrous board material), and laminate core. Alternatively, the cored package substrates, for example, can be built up layer by layer around a central core, with layers of conductive material (usually copper) separated by layers of insulating dielectric, with interlayer connections being formed with through holes or vias (microvias).

In accordance with some embodiment, as shown in FIG. 1, the substrate 102 includes a core CR and redistribution layers (RDLs) RD-1 and RD-2. In accordance with some embodiments, the core CR may be formed of an organic material, a glass material, a ceramic material, a semiconductor material, the like, or a combination thereof. The organic material may include polypropylene, prepreg (PP), fiberglass resin (e.g., FR-4), bismaleimide triazine (BT) resin, the like, or a combination thereof. The semiconductor material may include silicon, germanium, or a compound material, including silicon germanium, silicon carbide, gallium arsenic, silicon germanium carbide, the like, or a combination thereof. The redistribution layers RD-1 and RD-2 are disposed on the top surface and the bottom surface of the core CR, respectively. In accordance with some embodiments, each of the redistribution layers RD-1 and RD-2 includes conductive layers 102a, vias 102v disposed in one or more dielectric layers 102b, and conductive pads 102p.

In accordance with some embodiments, the dielectric layers 102b of the redistribution layers 210-1 and 210-2 are symmetrically disposed the top surface and the bottom surface of the core CR. For example, the number of dielectric layers 102b of the redistribution layer 210-1 may the same as the number of dielectric layers 102b of the redistribution layers 210-2. In accordance with some embodiments, the dielectric layers 102b may be formed of organic polymer, including polyimide (PI), polybenzoxazole (PBO), benzocyclobutene (BCB), epoxy, Ajinomoto build-up film (ABF), Bismaleimide-Triazine (BT resin), another suitable organic dielectric material, or a combination thereof, but it is not limited thereto. Alternatively, the dielectric layers 102b may be formed of silicon oxide, silicon nitride, silicon oxynitride, the like, or a combination thereof. In accordance with some embodiments, the dielectric layers 102b may be formed by a lamination process, a spin coating process, a chemical vapor deposition (CVD) process, or another applicable process. In accordance with some embodiment, the dielectric layers 102b may be patterned through one or more photolithography processes and/or etching processes.

It should be noted that the number of vias 102v, the number of conductive layers 102a and the number of dielectric layers 102b of the redistribution layers 210-1 and 210-2 shown in FIG. 1 are an example and the present disclosure is not limited thereto.

As shown in FIG. 1, the substrate 102 has separated holes TH (or through holes TH) embedded it. In accordance with some embodiments, the holes TH are formed passing through the core CR embedded it. In accordance with some embodiments, the holes TH are formed by a drilling process (e.g., mechanical drilling).

The conductive material 104 is disposed in the hole TH. In accordance with some embodiments, as shown in FIG. 1, the conductive material 104 may be formed as a thin conductive layer lining inner walls of the hole TH. The conductive material 104 in the hole TH may have a hollow pillar shape. In accordance with some embodiments, the conductive material 104 include copper or nickel-copper and are formed by a plating process, such as chemical plating, electroplating or electro-less plating. For example, the conductive material 104 may also be called a plated through hole (PTHs) 104.

As shown in FIG. 1, the substrate 102 of the semiconductor package structure 10 further includes a filling material 105 filling the remaining space of the hole TH and surrounded by the conductive material 104. In accordance with some embodiments, the filling material 105 may include a non-conductive material such as epoxy resin, or an ink. In accordance with some other embodiments, the filling material 105 may include a conductive material such as copper.

The conductive layers 102a are formed within the conductive layers 102b at different levels. Some of the conductive layers 102b are formed directly on the top surface and the bottom surface of the core CR, respectively. In accordance with some embodiments, the conductive layers 102a may fully cover the holes TH, the conductive material 104 lining the inner walls of the holes TH and the filling material 105 filling the holes TH. In addition, the conductive layers 102a may be electrically connected (coupled) to the conductive material 104 lining the inner walls of the holes TH.

In accordance with some embodiments, the conductive layers 102b at each of levels of the redistribution layers RD-1 and RD-2 may include a set of conductive traces (not shown) or conductive planes (also called ground planes) (not shown). In accordance with some embodiments, the conductive traces may include power trace segments, signal trace segments or ground trace segments, which are used for the input/output (I/O) connections of the semiconductor dies 300.

As shown in FIG. 1, the vias 102v disposed in the dielectric layers 102b of the redistribution layers RD-1 and RD-2. The vias 102v may be formed passing through the dielectric layers 102b of the redistribution layers RD-1 and RD-2 to be coupled to different levels of the conductive layers 102a. In accordance with some embodiments, the vias 102v may be formed by laser-drilling and a subsequent deposition process.

The conductive pads 102p are exposed to openings of solder mask layers (not shown) disposed close to the top surface 102s2 and the bottom surface 102s1 of the substrate 102. The conductive pads 102p are coupled to different terminals of the conductive traces. The conductive pads 102p close to the bottom surface 102s1 of the substrate 102 may be coupled to the conductive structures 110, and the conductive structures 110 may be mounted directly on the conductive pads 102p.

In accordance with some embodiments, the conductive layers 102b, the vias 102v and the conductive pads 102p include a conductive material, such as metals including copper, gold, silver, or other applicable metals. For example, the conductive layers 102b, the vias 102v and the conductive pads 102p may be formed of copper.

Moreover, in accordance with some embodiments, the semiconductor package structure 10 further includes one or more passive components 106 disposed within the substrate 102. For example, the passive components may be embedded in the core CR of the substrate 102. The passive components 106 may be coupled to the redistribution layer RD-1. In accordance with some embodiments, the passive component 106 may include a resistor, a capacitor, an inductor, or another suitable passive component. In accordance with some embodiments, the passive component 106 may be a deep trench capacitor (DTC).

As shown in FIG. 1, in accordance with some embodiments, the semiconductor package structure 10 further includes one or more passive components 108 disposed below the substrate 102. The passive components 108 may be disposed on the bottom surface 102s1 of the substrate 102 and adjacent to the conductive structures 110. In accordance with some embodiments, the passive component 108 may include a resistor, a capacitor, an inductor, or another suitable passive component. In accordance with some embodiments, the passive component 108 may be a land side capacitor (LSC).

As shown in FIG. 1, in accordance with some embodiments, the semiconductor package structure 10 may be a Chip-on-Wafer-on-Substrate (CoWoS) structure. For example, the semiconductor package structure 10 may include at least one wafer-level fan-out package FP (such as a Chip-on-Wafer (CoW) package) disposed over the substrate 102.

In accordance with some embodiments, the semiconductor package structure 10 includes the substrate 102, the fan-out package FP, an underfill 207, a molding compound 408, a thermal dissipation layer 502, a ring member 510, and conductive structures 110. The fan-out package FP of the semiconductor package structure 10 includes a substrate 202, one or more bridge structures 204, conductive connectors 206 and 208, an underfill 209, the semiconductor dies 300, memory components 400, and a dielectric layer 407.

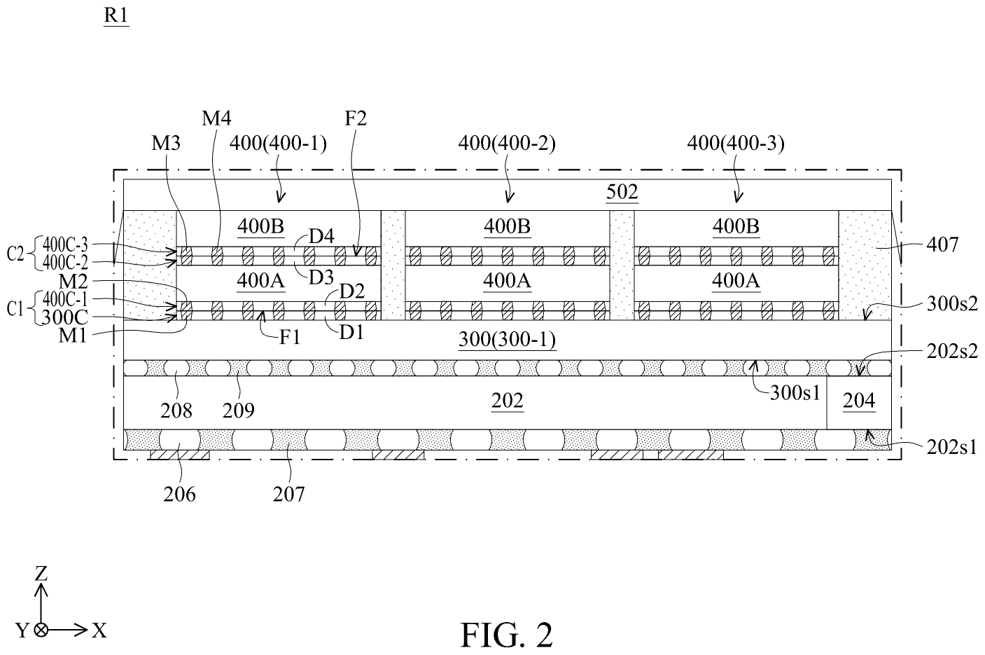

Please refer to FIG. 1 and FIG. 2. FIG. 2 is an enlarged diagram of area R1 in FIG. 1 in accordance with some embodiments of the present disclosure. Specifically, FIG. 2 illustrates a partially enlarged diagram of the fan-out package FP in accordance with some embodiments.

As shown in FIG. 1 and FIG. 2, the fan-out package FP is mounted on the substrate 102 opposite the conductive structures 110 by a bonding process using conductive connectors 206. The conductive connectors 206 may be in contact with and coupled to the substrate 202 and the conductive pads 102p of the substrate 102. In accordance with some embodiments, the conductive connectors 206 may include a conductive ball structure such as a copper ball, a conductive bump structure such as a copper bump or a solder bump structure, or a conductive pillar structure such as a copper pillar structure. For example, the conductive connectors 206 may be controlled collapse chip connection (C4) structures.

In accordance with some embodiment, the substrate 202 serves as an interposer. The substrate 202 is disposed between the substrate 102 and the semiconductor dies 300. The substrate 202 has a first surface 202s1 adjacent to the substrate 102 and a second surface 202s2 away from the substrate 102. In accordance with some embodiments, the substrate 102 includes one or more bridge structures 204 embedded therein. The bridge structures 204 may be coupled between the semiconductor dies 300. For example, the bridge structure 204 may be coupled between the semiconductor dies 300-1 and 300-2, and between the semiconductor dies 300-2 and 300-3. In other words, the semiconductor die 300-1 may be coupled to the semiconductor die 300-2 through the bridge structure 204, and the semiconductor die 300-2 may be coupled to the semiconductor die 300-2 through the bridge structure 204. In accordance with some embodiments, the bridge structure 204 may be coupled to the redistribution layer RD-1 of the substrate 102. In accordance with some embodiments, the bridge structure 204 may be disposed in a recess (not shown) formed in the upper portion of the substrate 202. The bridge structures 204 may overlap the semiconductor dies 300 in a normal direction of the substrate 202 (e.g., the Z direction in the figure). For example, the bridge structure 204 may vertically overlap both the semiconductor dies 300-1 and 300-2, or both the semiconductor dies 300-2 and 300-3.

In accordance with some embodiments, the bridge structure 204 may be a bridge die. Specifically, the bridge structure 204 may include a silicon body (not shown) and an interconnect structure (not shown) embedded in the silicon body (not shown). The interconnect structure (not shown) may include conductive lines and vias disposed in one or more dielectric layers, and conductive pads formed in the silicon body (not shown). The interconnect structure (not shown) may electrically couple the semiconductor dies to each other. In accordance with some embodiments, the bridge structure 204 may be a local silicon interconnect (LSI).

In accordance with some embodiments, the substrate 202 may further include one or more conductive traces (not shown), one or more conductive vias (not shown) disposed in one or more dielectric layers (not shown) and conductive pads (not shown). The conductive traces are coupled to the corresponding contact pads. The conductive pads are exposed to openings of the solder mask layer (not shown) and close to the substrate 102. The conductive elements 206 are disposed on and in contact with the corresponding contact pads (not shown). Therefore, the conductive elements 206 are coupled between the conductive pads of the fan-out package FP and the conductive pads 102p of the substrate 102.

As shown in FIG. 1 and FIG. 2, the underfill 207 may fill the gap between the substrate 202 and the substrate 102. In accordance with some embodiments, the underfill 207 may surround a lower portion of the substrate 202 and the conductive connectors 206, and is in contact with a portion of the substrate 102 to further reduce the thermal resistance from the fan-out package FP to the substrate 102. In addition, the underfill 207 may be disposed to compensate for differing coefficients of thermal expansion (CTEs) between the wafer-level fan-out package FP, the conductive connectors 206 and the substrate 102. In accordance with some embodiments, the underfill 207 may be formed of polymer, such as epoxy or another suitable material. In accordance with some embodiments, the underfill 207 may be dispensed with capillary force, and then may be cured through any suitable curing process.

As shown in FIG. 1 and FIG. 2, the semiconductor package structure 10 includes semiconductor dies 300 (including semiconductor dies 300-1, 300-2, and 300-3) disposed over the substrate 102. The semiconductor dies 300 each has a first surface 300sl adjacent to the substrate 102 and a second surface 300s2 away from the substrate 102. Specifically, the semiconductor dies 300 are arranged side-by-side in a direction perpendicular to the normal direction of the substrate 102 (e.g., the X direction in the figure). In accordance with some embodiments, the semiconductor dies 300 are mounted on the second surface 202s2 of the substrate 202 by a bonding process using conductive connectors 208. In accordance with some embodiments, the semiconductor dies 300 vertically overlap the bridge structure 204. The semiconductor dies 300 are coupled to the bridge structure 204 embedded in the substrate 202. In accordance with some embodiments, the conductive connectors 208 include a conductive ball structure such as a copper ball, a conductive bump structure such as a copper bump or a solder bump structure, or a conductive pillar structure such as a copper pillar structure. For example, the conductive connectors 208 may be microbumps, controlled collapse chip connection (C4) bumps, solder balls, ball grid array (BGA) balls, another suitable conductive connector, or a combination thereof.

In accordance with some embodiments, each of the semiconductor dies 300 (including semiconductor dies 300-1, 300-2, and 300-3) independently includes one or more system-on-chip (SoC) dies, system-on-integrated-circuits (SoIC) dies, the like, or any combination thereof. For example, the semiconductor dies 300 may each independently include one or more application specific integrated circuit (ASIC) dies, SoIC-X dies, Foveros dies, application processor (AP) dies, central processing unit (CPU) dies, graphics processing unit (GPU) dies, micro control unit (MCU) dies, microprocessor unit (MPU) dies, the like, or any combination thereof. In particular embodiments, the semiconductor dies 300 may include one or more ASIC dies. In accordance with some embodiments, the semiconductor dies 300-1, 300-2, and 300-3 may have different functions.

As shown in FIG. 1 and FIG. 2, the underfill 209 may fill the gap between the semiconductor dies 300 and the substrate 202. In accordance with some embodiments, the underfill 209 may surround the conductive connectors 208. In addition, the underfill 209 may be disposed to compensate for differing coefficients of thermal expansion (CTEs) between the semiconductor dies 300, the conductive connectors 208 and the substrate 202. In accordance with some embodiments, the underfill 209 may be formed of polymer, such as epoxy or another suitable material. In accordance with some embodiments, the underfill 209 may be dispensed with capillary force, and then may be cured through any suitable curing process.

Moreover, as shown in FIG. 1 and FIG. 2, the semiconductor package structure 10 includes the memory components 400 (including memory components 400-1, 400-2 and 400-3) disposed over the semiconductor dies 300. The memory components 400 vertically overlap the semiconductor dies 300. In other words, the memory components 400 may overlap the semiconductor die 300 along the normal direction of the substrate 202 (e.g., the Z direction in the figure). The memory components 400 are coupled to the memory component 300. Specifically, the memory components 400 are coupled to the memory component 300 through a hybrid bonding process.

As shown in FIG. 2, the semiconductor die 300 includes a bonding layer 300C disposed on the second surface 300s2 of the semiconductor die 300. The memory component 400 includes a bonding layer 400C-1 adjacent to the second surface 300s2 of the semiconductor die 300. Moreover, the memory component 400 is coupled to the semiconductor die 300 through a connection structure C1 formed by the bonding layer 300C and the bonding layer 400C-1. The bonding layer 300C faces and is directly bonded to the bonding layer 400C-1. In accordance with some embodiments, the connection structure C1 includes the hybrid bonding interface F1 of the bonding layer 300C and the bonding layer 400C-1. Specifically, the bonding layer 300C includes dielectric portions D1 and conductive portions M1, and the bonding layer 400C-1 includes dielectric portions D2 and conductive portions M2. In accordance with some embodiments, the hybrid bonding interface F1 includes a dielectric-to-dielectric bond between the dielectric portions D1 and the dielectric portions D2, and a metal-to-metal bond between the conductive portions M1 and the conductive portions M2. In accordance with some embodiments, the conductive portions M2 of the bonding layer 400C-1 may be disposed directly on and completely overlap the corresponding conductive portions M1 of the bonding layer 300C. In accordance with some embodiments, the conductive portions M1 and M2 may have the same dimensions. The dielectric portions D2 of the bonding layer 400C-1 may be disposed directly on and completely overlap the dielectric portions D1 of the bonding layer 300C. In accordance with some embodiments, the conductive portions M1 and M2 may include a conductive material, such as metals including copper, gold, silver, the like, or any combination thereof. For example, the conductive portions M1 and M2 may be formed of copper. In accordance with some embodiments, the dielectric portions D1 and D2 may include a low-k material, such as silicon oxide, silicon nitride, the like, or any combination thereof.

As shown in FIG. 2, in accordance with some embodiments, the memory components 400 (including memory components 400-1, 400-2 and 400-3) each includes a base die 400A (also called a core die) and one or more memory dies 400B stacked over the base die 400A. The memory components 400 may be arranged side-by-side in a direction perpendicular to the normal direction of the semiconductor die 300 (e.g., the X direction in the figure). The memory components 400 are disposed over the semiconductor die 300 and vertically overlap the semiconductor die 300. In accordance with some embodiments, the memory dies 400B stacked on each other and mounted on the base die 400A along the normal direction of the semiconductor die 300 (e.g., the Z direction in the figure). In other words, the memory dies 400B may overlap the base die 400A along the normal direction of the semiconductor die 300 (e.g., the Z direction in the figure). The memory dies 400B are coupled to the base die 400A. Specifically, the memory dies 400B are coupled to the base die 400A through a hybrid bonding process.

As shown in FIG. 2, the base die 400A includes a bonding layer 400C-2 disposed opposite the bonding layer 400C-1. The memory die 400B closest to the base die 400A includes a bonding layer 400C-3, and the bonding layer 400C-3 is adjacent to the bonding layer 400C-2. Moreover, the base die 400A is coupled to the memory die 400B through a connection structure C2 formed by the bonding layer 400C-2 and the bonding layer 400C-3. The bonding layer 400C-2 faces and is directly bonded to the bonding layer 400C-3. In accordance with some embodiments, the connection structure C2 includes the hybrid bonding interface F2 of the bonding layer 400C-2 and the bonding layer 400C-3. Specifically, the bonding layer 400C-2 includes dielectric portions D3 and conductive portions M3, and the bonding layer 400C-3 includes dielectric portions D4 and conductive portions M4. In accordance with some embodiments, the hybrid bonding interface F2 includes a dielectric-to-dielectric bond between the dielectric portions D3 and the dielectric portions D4, and a metal-to-metal bond between the conductive portions M3 and the conductive portions M4. In accordance with some embodiments, the conductive portions M3 of the bonding layer 400C-2 may be disposed directly on and completely overlap the corresponding conductive portions M4 of the bonding layer 400C-3. In accordance with some embodiments, the conductive portions M3 and M4 may have the same dimensions. The dielectric portions D4 of the bonding layer 400C-3 may be disposed directly on and completely overlap the dielectric portions D3 of the bonding layer 400C-2. In accordance with some embodiments, the conductive portions M3 and M4 may include a conductive material, such as metals including copper, gold, silver, the like, or any combination thereof. For example, the conductive portions M3 and M4 may be formed of copper. In accordance with some embodiments, the dielectric portions D3 and D4 may include a low-k material, such as silicon oxide, silicon nitride, the like, or any combination thereof.

In accordance with some embodiments, each of the memory components 400 may be a high-bandwidth memory (HBM). The base die 400A may include a dynamic random access memory (DRAM) controller die. In addition, each of memory dies 400B may include a dynamic random-access memory (DRAM) die.

In the embodiments where the memory component 400 includes a plurality of memory dies 400B, the memory dies 400B may be hybrid bonded each other and interconnected through conductive vias (not shown). For example, each of the memory dies 400B may include one or more conductive vias (not shown). The conductive vias may be through-silicon vias (TSVs). In accordance with some embodiments, the conductive vias may be formed of metal, such as copper, tungsten, tantalum, titanium, another suitable conductive material, an alloy thereof, or a combination thereof, but it is not limited thereto. In accordance with some embodiments, the conductive vias may be formed by a plating process, a chemical vapor deposition (CVD) process, a physical vapor deposition (PVD) process, or another applicable process.

As described above, the memory component 400 can be integrated into the semiconductor die 300 in a vertical stacking arrangement, which enables a smaller form factor compared to conventional package structures. The interconnect length between the semiconductor die 300 and the memory component 400 can be reduced (for example, reduced by about 1.5 to 2 reticle size), thereby improving electrical performance, such as lowering signal delay and enhancing power integrity. Moreover, the overall package footprint can be reduced, while increasing the memory bandwidth and storage (for example, increased at least by about 2-fold to 4-fold).

It should be noted that the number of bridge structures 204, the number of semiconductor dies 300, the number of memory components 400 and the number of memory dies 400B of the memory component 400 of the semiconductor package structure 10 shown in FIG. 1 and FIG. 2 are an example and the present disclosure is not limited thereto.

As shown in FIG. 1 and FIG. 2, the semiconductor package structure 10 may further include a dielectric layer 407 surrounding the memory components 400-1, 400-2 and 400-3. The dielectric layer 407 may fill the gap between the semiconductor dies 300 and the thermal dissipation layer 502. In accordance with some embodiments, the dielectric layer 407 may surround the memory components 400-1, 400-2 and 400-3. In accordance with some embodiments, the dielectric layer 407 may be formed of oxide, such as silicon oxide, the like, or any combination thereof, but it is not limited thereto. In accordance with some embodiments, the dielectric layer 407 may be formed by a lamination process, a spin coating process, a chemical vapor deposition (CVD) process, or another applicable process. In accordance with some embodiment, the dielectric layer 407 may be patterned through one or more photolithography processes and/or etching processes.

In accordance with some embodiments, the semiconductor package structure 10 further includes a thermal dissipation layer 502 disposed over the memory components 400. The thermal dissipation layer 502 may cover the top surfaces of the memory components 400 and the dielectric layer 407. In accordance with some embodiments, the thermal dissipation layer 502 may be in contact with the memory components 400 to enhance its thermal conductivity. As shown in FIG. 1, the thermal dissipation layer 502 may be continuously disposed over multiple memory components 400. In accordance with some other embodiments, the thermal dissipation layer 502 may be discontinuously disposed over multiple memory components 400. For example, the thermal dissipation layer 502 may include separate portions disposed over the memory components 400 respectively. In accordance with some embodiments, the thermal dissipation layer 502 may be formed of thermal grease, thermal gel, thermal conductive adhesive, phase change material, phase change metal alloy, metal, polymer, another suitable material, or a combination thereof, but it is not limited thereto.

In accordance with some embodiments, the semiconductor package structure further includes a molding compound 408. The molding compound 408 is disposed on and in contact with the substrate 202. The molding compound 408 may also be in contact with the substrate 102. The molding compound 408 may laterally surround the dielectric layer 407, the semiconductor dies 300 and the substrate 202. In accordance with some embodiments, the molding compound 408 may be formed of a nonconductive material, such as an epoxy, a resin, a moldable polymer, or the like. In accordance with some embodiments, the molding compound 408 may be formed by a molding process including compression or injection process. For example, the molding compound 408 may be applied while substantially liquid, and then may be cured through a chemical reaction, such as in an epoxy or resin. In accordance with some other embodiments, the molding compound 408 may be an ultraviolet (UV) or thermally cured polymer applied as a gel or malleable solid capable of being disposed around the dielectric layer 407, the semiconductor dies 300 and the substrate 202, and then may be cured using a UV or thermally curing process. The molding compound 408 may be cured with a mold (not shown).

As shown in FIG. 1, in accordance with some embodiments, the semiconductor package structure 10 further includes a ring member 510 mounted on the substrate 102 opposite the conductive structures 110 using an adhesive layer (not shown). The ring member 510 may be adhered onto the substrate 102 along edges of the substrate 102. The ring member 510 may laterally surround the fan-out package FP. Specifically, the ring member 510 may laterally surround substrate 202, the semiconductor dies 300, the memory components 400, the dielectric layer 407 and the molding compound 408.

The ring member 510 may include a stiffener ring. In accordance with some embodiments, the ring member 510 is used for warpage control to reduce the high stress experienced by bonded various materials in the semiconductor package structure during cycles of heating and cooling. The ring member 510 may provide extra support to the semiconductor package structure 10 thus reducing warpage, preventing bending, and maintaining planarity of the substrate 102. In accordance with some embodiments, the ring member 510 may be separated from the molding compound 408 by a distance. In accordance with some embodiments, edges of the ring member 510 are leveled with the corresponding edges of the substrate 102. Therefore, the edges of the ring member 510 and the edges of the substrate 102 may collectively serve as edges of the semiconductor package structure 10. In accordance with some embodiments, the ring member 510 includes molding compound, epoxy, metal (e.g., copper), another suitable material, or a combination thereof, but it is not limited thereto. In accordance with some embodiments, the ring member 510 may be formed by a compression molding process, a transfer molding process, a dispensing process, a PVD process, another applicable process, or a combination thereof.

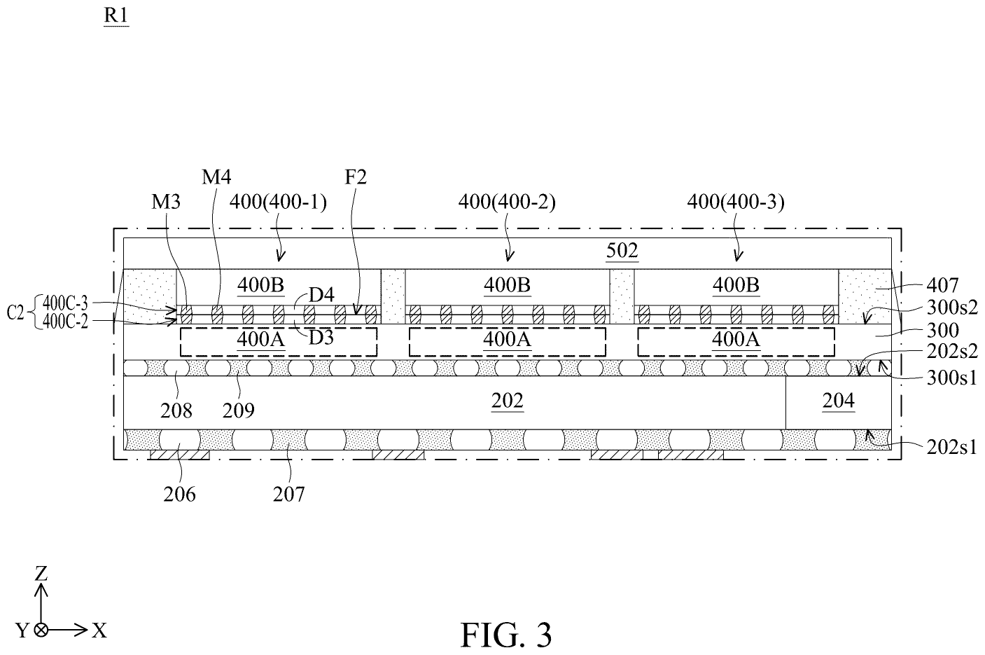

Refer to FIG. 3, which is an enlarged diagram of area R1 in FIG. 1 in accordance with some other embodiments of the present disclosure. Elements of the embodiments that are the same or similar to those previously described with reference to FIG. 1 are not repeated herein for brevity.

As shown in FIG. 3, the base die 400A of the memory component 400 may be integrated into the semiconductor die 300. The memory component 400 includes the memory die 400B vertically overlapping the semiconductor die 300. Specifically, in accordance with some embodiments, functionality of the base die 400A may be integrated into the semiconductor die 300. Alternatively, circuitry corresponding to the base die 400A may be integrated into the semiconductor die 300. For clarity of illustration, the base die 400A integrated into the semiconductor die 300 is depicted by a dotted box. In accordance with some embodiments, the semiconductor die 300 includes first circuitry configured to control access to the memory component 400. In accordance with some embodiments, the semiconductor die 300 includes second circuitry configured to control access within the semiconductor die 300, and the first circuitry is integrated into the second circuitry. In accordance with some embodiments, the second circuitry includes first circuitry configured to provide an interface for controlling access to the memory die 400B of the memory component 400. In accordance with some embodiments, the memory die 400B is stacked on the semiconductor die 300, and a separate base die 400A is not required since its function is integrated into the semiconductor die 300. In other words, such a configuration may be implemented without a base die.

In accordance with some other embodiments, the memory die 400B is stacked on the base die 400A, and the base die 400A is embedded in the semiconductor die 300. The memory die 400B may protrude from the second surface 300s2 of the substrate 300 along the normal direction of the semiconductor die 300 (e.g., the Z direction in the figure). For example, in these embodiments, the base die 400A integrated into the semiconductor die 300 may be coupled to the substrate 202 and the bridge structure 204 through the conductive connectors 206. Moreover, the base die 400A may be coupled to the memory die 400B through the connection structure C2 formed by the bonding layer 400C-2 and the bonding layer 400C-3. The structure, arrangements, materials and processes of the connection structure C2 may be understood by referring to those of the connection structure C2 shown in FIG. 2, and are not repeated herein for brevity.

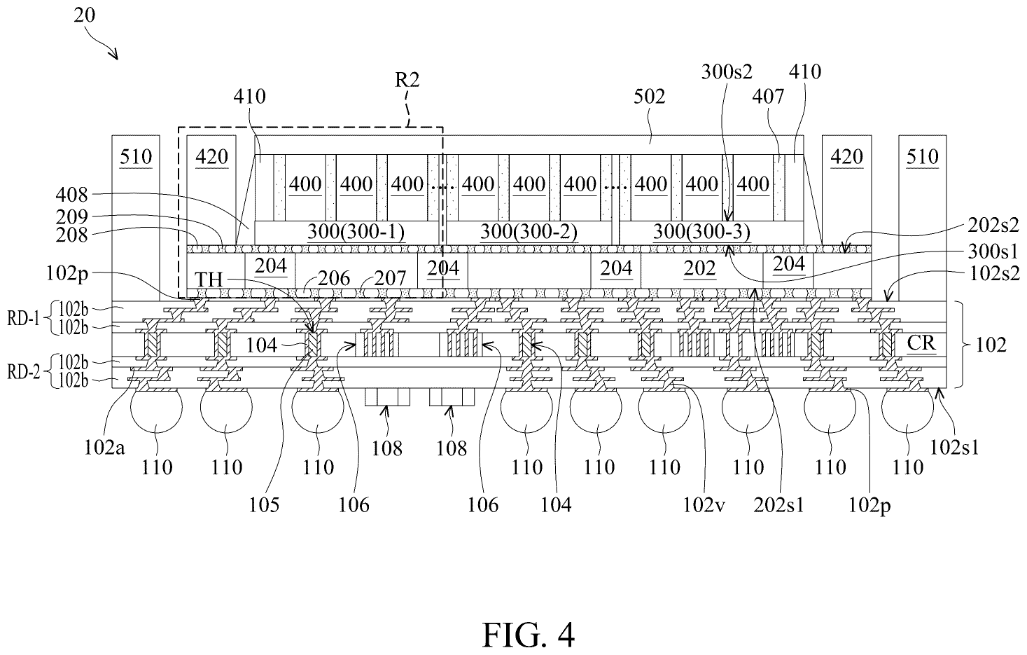

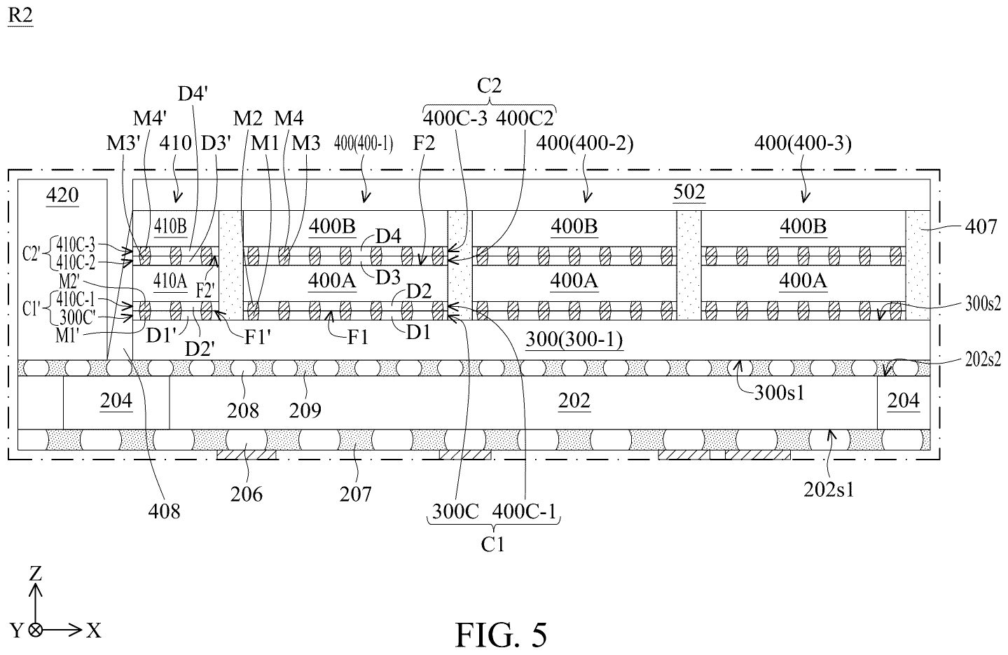

Refer to FIG. 4 and FIG. 5. FIG. 4 is a cross-sectional diagram of an exemplary semiconductor package structure 20 in accordance with some embodiments of the present disclosure. FIG. 5 is an enlarged diagram of area R2 in FIG. 4 in accordance with some embodiments of the present disclosure. Elements of the embodiments that are the same or similar to those previously described with reference to FIG. 1 and FIG. 2 are not repeated herein for brevity.

Compared with the semiconductor package structure 10, the semiconductor package structure 20 further includes one or more memory components 420 disposed over the substrate 102. The memory component 420 is adjacent to the semiconductor die 300. In accordance with some embodiments, the conductive connectors 208 are disposed between the memory component 420 and the substrate 202. The memory component 420 may vertically overlap the bridge structure 204. The memory component 420 is coupled to the bridge structure 204 through the conductive connectors 208. In accordance with some embodiments, the memory component 420 is coupled to the semiconductor die 300 (300-1) through the bridge structure 204.

In accordance with some embodiments, the memory component 420 may be a high-bandwidth memory (HBM). The memory component 420 may also include a base die (not shown) and memory dies (not shown) stacked on the base die. The base die may include a dynamic random access memory (DRAM) controller die. The memory die may include a dynamic random-access memory (DRAM) die. In accordance with some embodiments, the height of the memory component 420 may be greater than the height of the memory component 400. The memory component 420 can provide additional memory capacity for the semiconductor package structure 20.

Furthermore, in accordance with some embodiments, the semiconductor package structure 20 may further include a semiconductor die 410 disposed over the semiconductor die 300 and adjacent to the memory component 400. The semiconductor die 410 and the memory components 400 may be arranged side-by-side in a direction perpendicular to the normal direction of the semiconductor die 300 (e.g., the X direction in the figure). The semiconductor die 410 may vertically overlap the semiconductor die 300. In accordance with some embodiments, the semiconductor die 410 may include a lower portion 410A and an upper portion 410B disposed on the lower portion 410A. The upper portion 410B may be coupled to the lower portion 410A. Specifically, the upper portion 410B may be coupled to the lower portion 410A through a hybrid bonding process.

As shown in FIG. 5, in accordance with some embodiments, the semiconductor die 300 includes the bonding layer 300C′ disposed on the second surface 300s2 of the semiconductor die 300. The lower portion 410A includes a bonding layer 410C-1 adjacent to the second surface 300s2 of the semiconductor die 300. The lower portion 410A may be coupled to the semiconductor die 300 through a connection structure C1′ formed by the bonding layer 300C′ and the bonding layer 410C-1. The bonding layer 300C′ faces and is directly bonded to the bonding layer 410C-1. In accordance with some embodiments, the connection structure C1′ includes the hybrid bonding interface F1′ of the bonding layer 300C′ and the bonding layer 410C-1. Specifically, the bonding layer 300C′ includes dielectric portions D1′ and conductive portions M1′, and the bonding layer 410C-1 includes dielectric portions D2′ and conductive portions M2′. In accordance with some embodiments, the hybrid bonding interface F1′ includes a dielectric-to-dielectric bond between the dielectric portions D1′ and the dielectric portions D2′, and a metal-to-metal bond between the conductive portions M1′ and the conductive portions M2′. In accordance with some embodiments, the conductive portions M2′ of the bonding layer 410C-1 may be disposed directly on and completely overlap the corresponding conductive portions M1′ of the bonding layer 300C′. In accordance with some embodiments, the conductive portions M1′ and M2′ may have the same dimensions. The dielectric portions D2′ of the bonding layer 410C-1 may be disposed directly on and completely overlap the dielectric portions D1′ of the bonding layer 300C′. In accordance with some embodiments, the conductive portions M1′ and M2′ may include a conductive material, such as metals including copper, gold, silver, the like, or any combination thereof. For example, the conductive portions M1′ and M2′ may be formed of copper. In accordance with some embodiments, the dielectric portions D1′ and D2′ may include a low-k material, such as silicon oxide, silicon nitride, the like, or any combination thereof.

In accordance with some embodiments, the lower portion 410A includes a bonding layer 410C-2 disposed opposite the bonding layer 400C-1. The upper portion 410B closest to the lower portion 410A includes a bonding layer 410C-3, and the bonding layer 410C-3 is adjacent to the bonding layer 410C-2. Moreover, the lower portion 410A is coupled to the upper portion 410B through a connection structure C2′ formed by the bonding layer 410C-2 and the bonding layer 410C-3. The bonding layer 410C-2 faces and is directly bonded to the bonding layer 410C-3. In accordance with some embodiments, the connection structure C2′ includes the hybrid bonding interface F2′ of the bonding layer 410C-2 and the bonding layer 410C-3. Specifically, the bonding layer 410C-2 includes dielectric portions D3′ and conductive portions M3′, and the bonding layer 410C-3 includes dielectric portions D4′ and conductive portions M4′. In accordance with some embodiments, the hybrid bonding interface F2′ includes a dielectric-to-dielectric bond between the dielectric portions D3′ and the dielectric portions D4′, and a metal-to-metal bond between the conductive portions M3′ and the conductive portions M4′. In accordance with some embodiments, the conductive portions M3′ of the bonding layer 410C-2 may be disposed directly on and completely overlap the corresponding conductive portions M4′ of the bonding layer 410C-3. In accordance with some embodiments, the conductive portions M3′ and M4′ may have the same dimensions. The dielectric portions D4′ of the bonding layer 410C-3 may be disposed directly on and completely overlap the dielectric portions D3′ of the bonding layer 410C-2. In accordance with some embodiments, the conductive portions M3′ and M4′ may include a conductive material, such as metals including copper, gold, silver, the like, or any combination thereof. For example, the conductive portions M3′ and M4′ may be formed of copper. In accordance with some embodiments, the dielectric portions D3′ and D4′ may include a low-k material, such as silicon oxide, silicon nitride, the like, or any combination thereof.

In accordance with some embodiments, the semiconductor die 410 serves as a dummy die. In accordance with some other embodiments, the semiconductor die 410 may be a functional die. The semiconductor die 410 may perform different function from that of the memory component 400.

The structure, arrangements, materials and processes of the substrate 102, the substrate 202, the conductive structures 110, the conductive connectors 206 and 208, the underfills 207 and 209, the semiconductor dies 300, the memory components 400, the dielectric layer 407, the molding compound 408, the thermal dissipation layer 502, and the ring member 510 of the semiconductor package structure 20 may be understood by referring to those of the substrate 102, the substrate 202, the conductive structures 110, the conductive connectors 206 and 208, the underfills 207 and 209, the semiconductor dies 300, the memory components 400, the dielectric layer 407, the molding compound 408, the thermal dissipation layer 502, and the ring member 510 of the semiconductor package structure 10 (e.g., shown in FIG. 1 and FIG. 2), and are not repeated herein for brevity.

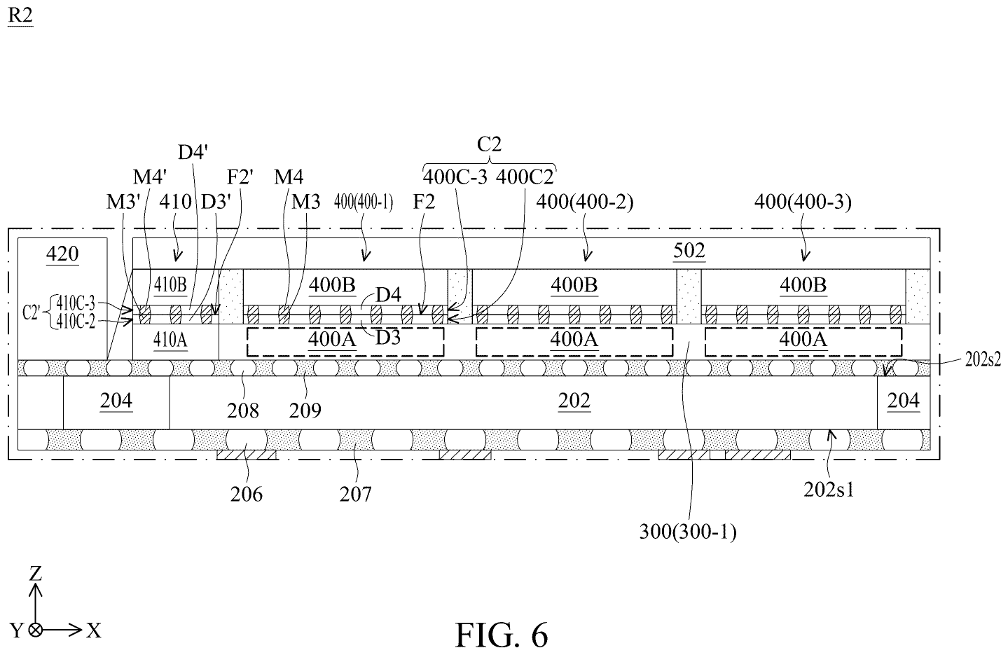

Refer to FIG. 6, which is an enlarged diagram of area R2 in FIG. 4 in accordance with some other embodiments of the present disclosure. Elements of the embodiments that are the same or similar to those previously described with reference to FIG. 4 are not repeated herein for brevity.

As shown in FIG. 6, the base die 400A of the memory component 400 may be integrated into the semiconductor die 300. The memory component 400 includes the memory die 400B vertically overlapping the semiconductor die 300. Specifically, in accordance with some embodiments, functionality of the base die 400A may be integrated into the semiconductor die 300. Alternatively, circuitry corresponding to the base die 400A may be integrated into the semiconductor die 300. In accordance with some embodiments, the semiconductor die 300 includes first circuitry configured to control access to the memory component 400. In accordance with some embodiments, the semiconductor die 300 includes second circuitry configured to control access within the semiconductor die 300, and the first circuitry is integrated into the second circuitry. In accordance with some embodiments, the second circuitry includes first circuitry configured to provide an interface for controlling access to the memory die 400B of the memory component 400. In accordance with some embodiments, the memory die 400B is stacked on the semiconductor die 300, and a separate base die 400A is not required since its function is integrated into the semiconductor die 300. In other words, such a configuration may be implemented without a base die.

In accordance with some other embodiments, the memory die 400B is stacked on the base die 400A, and the base die 400A is embedded in the semiconductor die 300. The memory die 400B may protrude from the second surface 300s2 of the substrate 300 along the normal direction of the semiconductor die 300 (e.g., the Z direction in the figure). For example, in these embodiments, the base die 400A integrated into the semiconductor die 300 may be coupled to the substrate 202 and the bridge structure 204 through the conductive connectors 206. Moreover, the base die 400A may be coupled to the memory die 400B through the connection structure C2 formed by the bonding layer 400C-2 and the bonding layer 400C-3. The structure, arrangements, materials and processes of the connection structure C2 in area R2 of the semiconductor package structure 20 may be understood by referring to those of the connection structure C2 in area R1 of the semiconductor package structure 10 (e.g., shown in FIG. 3), and are not repeated herein for brevity.

In accordance with some embodiments, the upper portion 410B is stacked on the lower portion 410A, and the lower portion 410A is embedded in the semiconductor die 300. The upper portion 410B may protrude from the second surface 300s2 of the substrate 300 along the normal direction of the semiconductor die 300 (e.g., the Z direction in the figure). For example, in these embodiments, the lower portion 410A integrated into the semiconductor die 300 may be coupled to the substrate 202 and the bridge structure 204 through the conductive connectors 206. Moreover, the lower portion 410A may be coupled to the upper portion 410B through the connection structure C2′ formed by the bonding layer 410C-2 and the bonding layer 410C-3. The structure, arrangements, materials and processes of the connection structure C2′ may be understood by referring to those of the connection structure C2′ shown in FIG. 5, and are not repeated herein for brevity.

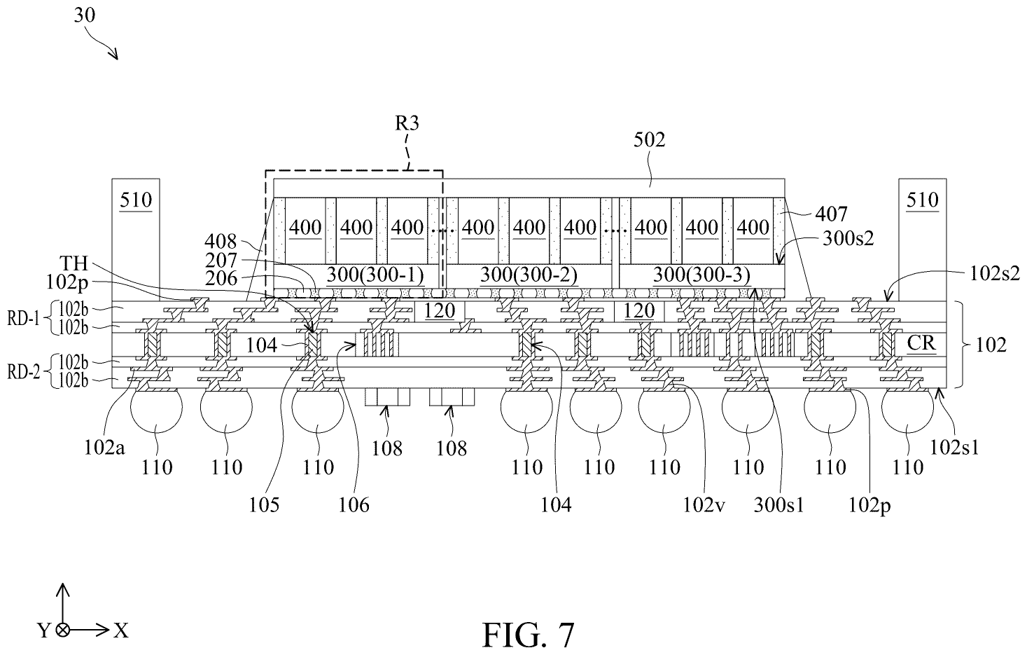

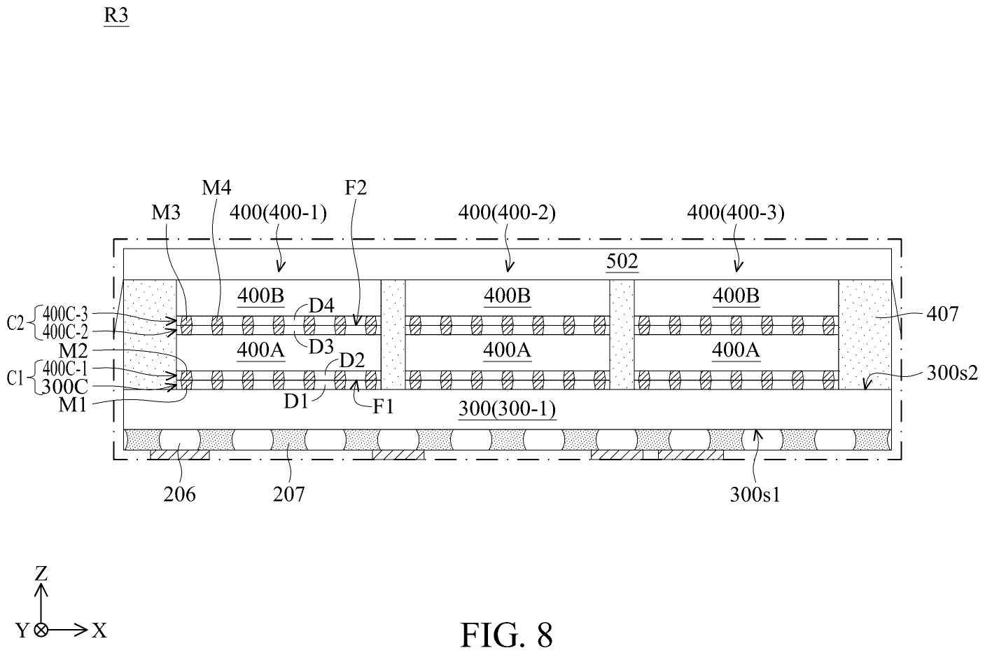

Refer to FIG. 7 and FIG. 8. FIG. 7 is a cross-sectional diagram of an exemplary semiconductor package structure 30 in accordance with some embodiments of the present disclosure. FIG. 8 is an enlarged diagram of area R3 in FIG. 7 in accordance with some embodiments of the present disclosure. Elements of the embodiments that are the same or similar to those previously described with reference to FIG. 1 are not repeated herein for brevity.

As shown in FIG. 7, in accordance with some embodiments, the semiconductor package structure 30 may adopt an embedded multi-die interconnect bridge (EMIB) structure. The semiconductor package structure 30 includes one or more bridge structures 120 embedded in the substrate 102. The bridge structures 120 may be coupled between the semiconductor dies 300. For example, the bridge structure 120 may be coupled between the semiconductor dies 300-1 and 300-2, and between the semiconductor dies 300-2 and 300-3. In other words, the semiconductor die 300-1 may be coupled to the semiconductor die 300-2 through the bridge structure 120, and the semiconductor die 300-2 may be coupled to the semiconductor die 300-2 through the bridge structure 120. In accordance with some embodiments, the bridge structure 120 may be coupled to the redistribution layer RD-1 of the substrate 102. In accordance with some embodiments, the bridge structure 120 may be disposed in a recess (not shown) formed in the upper portion of the substrate 102. The bridge structures 120 may overlap the semiconductor dies 300 in a normal direction of the substrate 202 (e.g., the Z direction in the figure). For example, the bridge structure 120 may vertically overlap both the semiconductor dies 300-1 and 300-2, or both the semiconductor dies 300-2 and 300-3.

In accordance with some embodiments, the bridge structure 120 may be a bridge die. Specifically, the bridge structure 120 may include a silicon body (not shown) and an interconnect structure (not shown) embedded in the silicon body (not shown). The interconnect structure (not shown) may include conductive lines and vias disposed in one or more dielectric layers, and conductive pads formed in the silicon body (not shown). The interconnect structure (not shown) may electrically couple the semiconductor dies to each other. In accordance with some embodiments, the bridge structure 120 may be an embedded multi-die interconnect bridge (EMIB).

As shown in FIG. 7 and FIG. 8, the semiconductor dies 300 are mounted on the second surface 102s2 of the substrate 102 by a bonding process using conductive connectors 206. In accordance with some embodiments, the conductive connectors 206 include a conductive ball structure such as a copper ball, a conductive bump structure such as a copper bump or a solder bump structure, or a conductive pillar structure such as a copper pillar structure. For example, the conductive connectors 206 may be microbumps, controlled collapse chip connection (C4) bumps, solder balls, ball grid array (BGA) balls, another suitable conductive connector, or a combination thereof. Moreover, in this embodiment, the underfill 207 may fill the gap between the semiconductor dies 300 and the substrate 102. In accordance with some embodiments, the underfill 207 may surround a lower portion of the semiconductor dies 300 and the conductive connectors 206, and is in contact with a portion of the substrate 102 to further reduce the thermal resistance from the semiconductor dies 300 to the substrate 102. In addition, the underfill 207 may be disposed to compensate for differing coefficients of thermal expansion (CTEs) between the semiconductor dies 300, the conductive connectors 206 and the substrate 102. In accordance with some embodiments, the underfill 207 may be formed of polymer, such as epoxy or another suitable material. In accordance with some embodiments, the underfill 207 may be dispensed with capillary force, and then may be cured through any suitable curing process.

As shown in FIG. 8, the memory component 400 is coupled to the semiconductor die 300 through the connection structure C1 formed by the bonding layer 300C and the bonding layer 400C-1. Specifically, the base die 400A is coupled to the semiconductor die 300 through the connection structure C1. Moreover, the base die 400A is coupled to the memory die 400B through the connection structure C2 formed by the bonding layer 400C-2 and the bonding layer 400C-3.

The structure, arrangements, materials and processes of the substrate 102, the conductive structures 110, the semiconductor dies 300, the memory components 400, the dielectric layer 407, the molding compound 408, the thermal dissipation layer 502, and the ring member 510 of the semiconductor package structure 30 may be understood by referring to those of the substrate 102, the conductive structures 110, the semiconductor dies 300, the memory components 400, the dielectric layer 407, the molding compound 408, the thermal dissipation layer 502, and the ring member 510 of the semiconductor package structure 10 (e.g., shown in FIG. 1 and FIG. 2), and are not repeated herein for brevity.

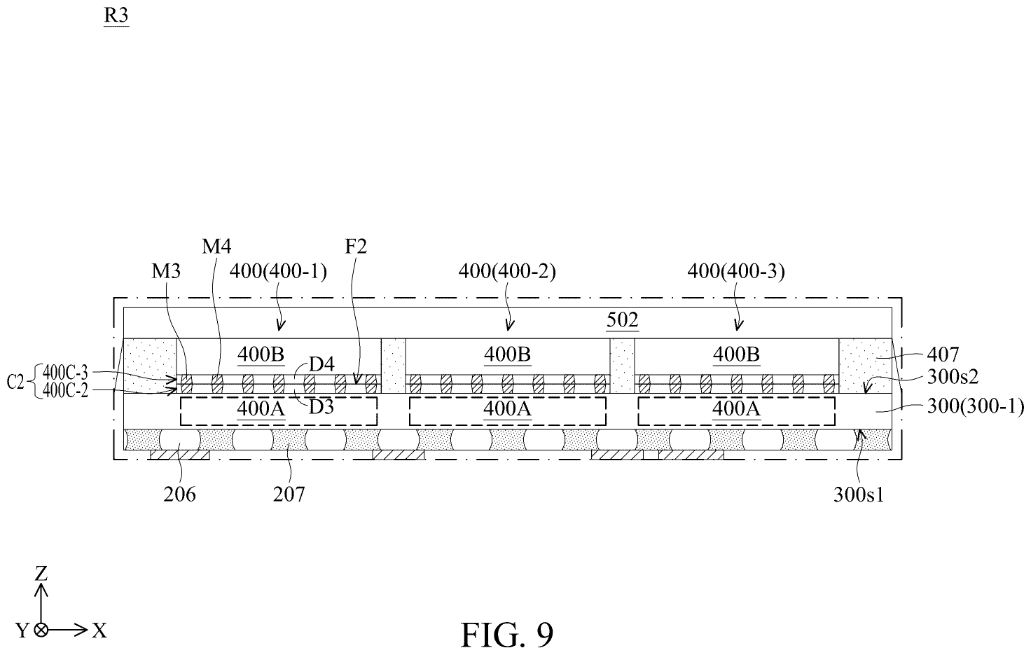

Refer to FIG. 9, which is an enlarged diagram of area R3 in FIG. 7 in accordance with some other embodiments of the present disclosure. Elements of the embodiments that are the same or similar to those previously described with reference to FIG. 7 are not repeated herein for brevity.

As shown in FIG. 9, the base die 400A of the memory component 400 may be integrated into the semiconductor die 300. The memory component 400 includes the memory die 400B vertically overlapping the semiconductor die 300. Specifically, in accordance with some embodiments, functionality of the base die 400A may be integrated into the semiconductor die 300. Alternatively, circuitry corresponding to the base die 400A may be integrated into the semiconductor die 300. In accordance with some embodiments, the semiconductor die 300 includes first circuitry configured to control access to the memory component 400. In accordance with some embodiments, the semiconductor die 300 includes second circuitry configured to control access within the semiconductor die 300, and the first circuitry is integrated into the second circuitry. In accordance with some embodiments, the second circuitry includes first circuitry configured to provide an interface for controlling access to the memory die 400B of the memory component 400. In accordance with some embodiments, the memory die 400B is stacked on the semiconductor die 300, and a separate base die 400A is not required since its function is integrated into the semiconductor die 300. In other words, such a configuration may be implemented without a base die.

In accordance with some other embodiments, the memory die 400B is stacked on the base die 400A, and the base die 400A is embedded in the semiconductor die 300. The memory die 400B may protrude from the second surface 300s2 of the substrate 300 along the normal direction of the semiconductor die 300 (e.g., the Z direction in the figure). For example, in these embodiments, the base die 400A integrated into the semiconductor die 300 may be coupled to the substrate 202 and the bridge structure 204 through the conductive connectors 206. Moreover, the base die 400A may be coupled to the memory die 400B through the connection structure C2 formed by the bonding layer 400C-2 and the bonding layer 400C-3. The structure, arrangements, materials and processes of the connection structure C2 may be understood by referring to those of the connection structure C2 shown in FIG. 2, and are not repeated herein for brevity.

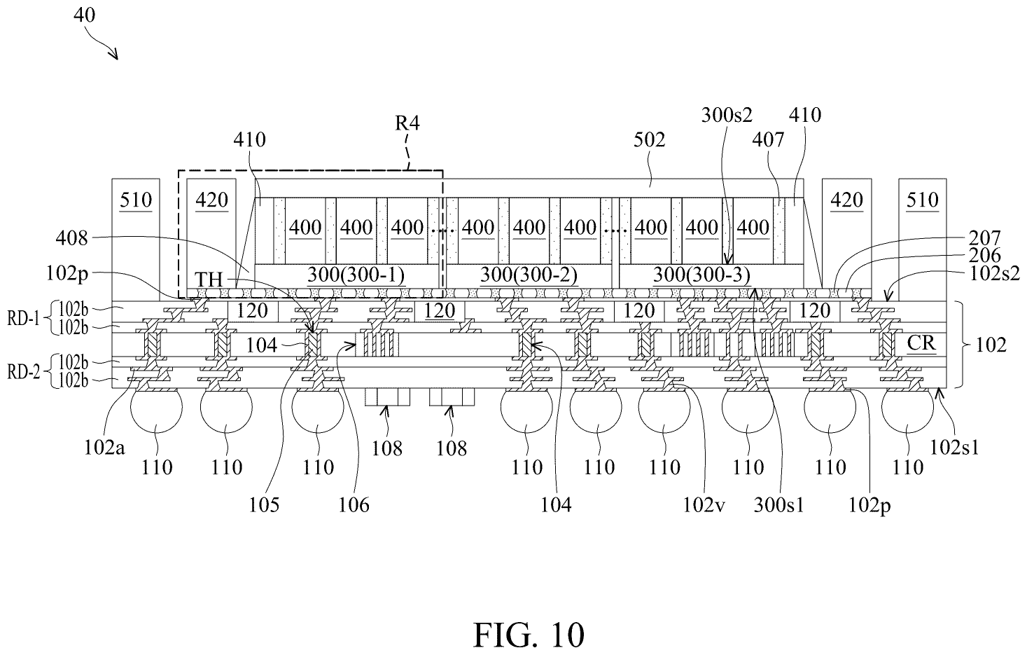

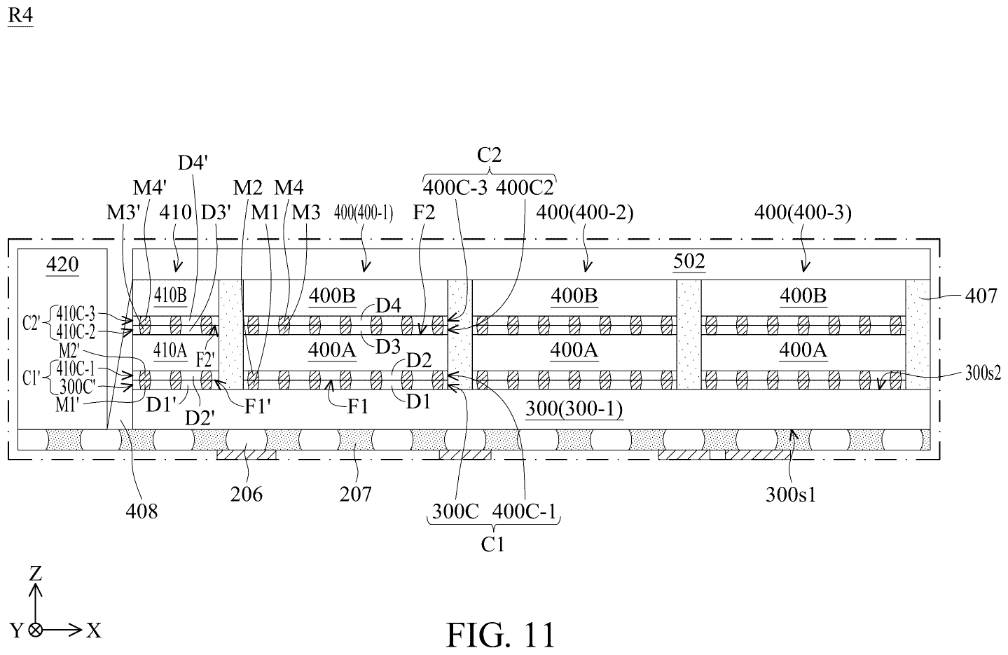

Refer to FIG. 10 and FIG. 11. FIG. 10 is a cross-sectional diagram of an exemplary semiconductor package structure 40 in accordance with some embodiments of the present disclosure. FIG. 11 is an enlarged diagram of area R4 in FIG. 10 in accordance with some embodiments of the present disclosure. Elements of the embodiments that are the same or similar to those previously described with reference to FIG. 7 are not repeated herein for brevity.

Compared with the semiconductor package structure 30, the semiconductor package structure 40 further includes one or more memory components 420 disposed over the substrate 102. The memory component 420 is adjacent to the semiconductor die 300. In accordance with some embodiments, the conductive connectors 206 are disposed between the memory component 420 and the substrate 102. The memory component 420 may vertically overlap the bridge structure 120. The memory component 420 is coupled to the bridge structure 120 through the conductive connectors 206. In accordance with some embodiments, the memory component 420 is coupled to the semiconductor die 300 (300-1) through the bridge structure 102.

The structure, arrangements, materials and processes of the substrate 102, the conductive structures 110, the conductive connectors 206, the underfills 207, the semiconductor dies 300, the memory components 400, the dielectric layer 407, the semiconductor die 410, the memory component 420, the molding compound 408, the thermal dissipation layer 502, and the ring member 510 of the semiconductor package structure 40 may be understood by referring to those of the substrate 102, the conductive structures 110, the conductive connectors 206, the underfills 207, the semiconductor dies 300, the memory components 400, the dielectric layer 407, the semiconductor die 410, the memory component 420, the molding compound 408, the thermal dissipation layer 502, and the ring member 510 of the semiconductor package structure 20 (e.g., shown in FIG. 4 and FIG. 5), and are not repeated herein for brevity.

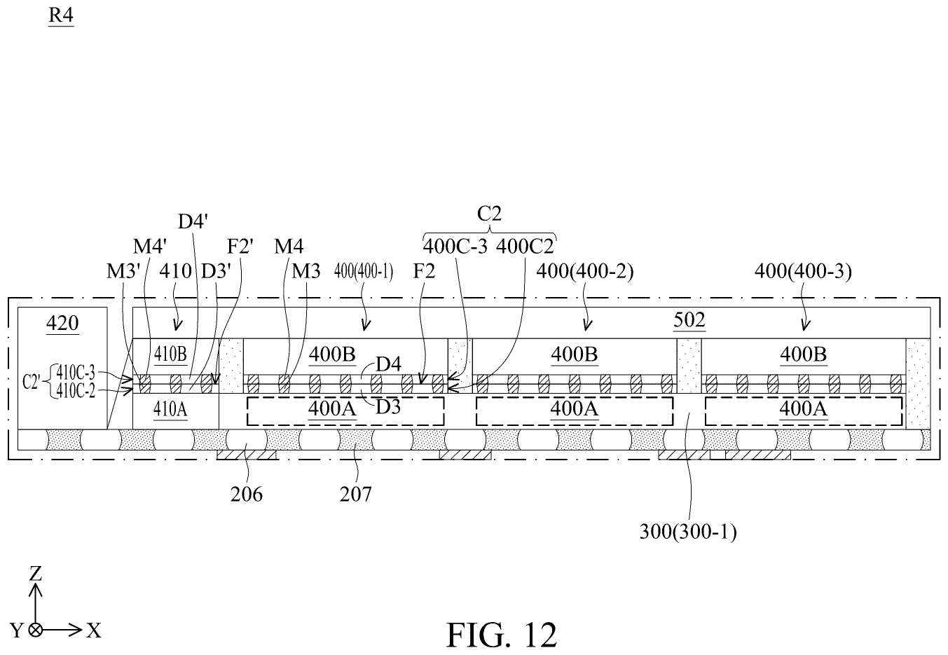

Refer to FIG. 12, which is an enlarged diagram of area R4 in FIG. 10 in accordance with some other embodiments of the present disclosure. Elements of the embodiments that are the same or similar to those previously described with reference to FIG. 10 are not repeated herein for brevity.

As shown in FIG. 12, the base die 400A of the memory component 400 may be integrated into the semiconductor die 300. The memory component 400 includes the memory die 400B vertically overlapping the semiconductor die 300. Specifically, in accordance with some embodiments, functionality of the base die 400A may be integrated into the semiconductor die 300. Alternatively, circuitry corresponding to the base die 400A may be integrated into the semiconductor die 300. In accordance with some embodiments, the semiconductor die 300 includes first circuitry configured to control access to the memory component 400. In accordance with some embodiments, the semiconductor die 300 includes second circuitry configured to control access within the semiconductor die 300, and the first circuitry is integrated into the second circuitry. In accordance with some embodiments, the second circuitry includes first circuitry configured to provide an interface for controlling access to the memory die 400B of the memory component 400. In accordance with some embodiments, the memory die 400B is stacked on the semiconductor die 300, and a separate base die 400A is not required since its function is integrated into the semiconductor die 300. In other words, such a configuration may be implemented without a base die.

In accordance with some other embodiments, the memory die 400B is stacked on the base die 400A, and the base die 400A is embedded in the semiconductor die 300. The memory die 400B may protrude from the second surface 300s2 of the substrate 300 along the normal direction of the semiconductor die 300 (e.g., the Z direction in the figure). For example, in these embodiments, the base die 400A integrated into the semiconductor die 300 may be coupled to the substrate 202 and the bridge structure 204 through the conductive connectors 206. Moreover, the base die 400A may be coupled to the memory die 400B through the connection structure C2 formed by the bonding layer 400C-2 and the bonding layer 400C-3. The structure, arrangements, materials and processes of the connection structure C2 in area R4 of the semiconductor package structure 40 may be understood by referring to those of the connection structure C2 in area R1 of the semiconductor package structure 10 (e.g., shown in FIG. 3), and are not repeated herein for brevity.

In accordance with some embodiments, the upper portion 410B is stacked on the lower portion 410A, and the lower portion 410A is embedded in the semiconductor die 300. The upper portion 410B may protrude from the second surface 300s2 of the substrate 300 along the normal direction of the semiconductor die 300 (e.g., the Z direction in the figure). For example, in these embodiments, the lower portion 410A integrated into the semiconductor die 300 may be coupled to the substrate 202 and the bridge structure 204 through the conductive connectors 206. Moreover, the lower portion 410A may be coupled to the upper portion 410B through the connection structure C2′ formed by the bonding layer 410C-2 and the bonding layer 410C-3. The structure, arrangements, materials and processes of the connection structure C2′ may be understood by referring to those of the connection structure C2′ shown in FIG. 11, and are not repeated herein for brevity.

In accordance with some embodiments, the semiconductor package structure may use a chiplet architecture to split a large, single semiconductor die into multiple smaller functional semiconductor dies (called chiplets) fabricated in different technology nodes. Each chiplet may have improved device performance and fabrication yields. In addition, the semiconductor package structure may have a reduced fabrication cost.

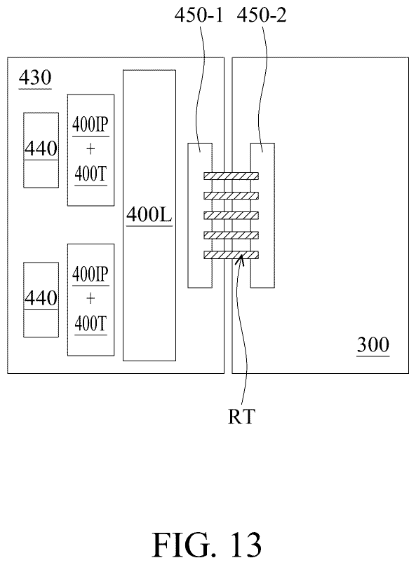

Refer to FIG. 13, which is a chiplet platform architecture diagram of an exemplary semiconductor package structure in accordance with some embodiments of the present disclosure. FIG. 13 schematically illustrates an architectural relationship between a chiplet platform 430 and a semiconductor die 300.

As shown in FIG. 13, a chiplet platform 430 may include a plurality of functional blocks. In accordance with some embodiments, the chiplet platform 430 may include an integrated module including a memory intellectual property block 400IP and a memory controller 400T with associated logic circuitry. In accordance with some embodiments, the memory intellectual property block 400IP is a high-bandwidth memory intellectual property (HBM IP). In accordance with some embodiments, the base die 400A serves as the memory controller with associated logic circuitry. In other words, the chiplet platform 430 may include circuitry corresponding to the base die 400A, the circuitry being configured to function as the memory controller 400T. Moreover, in accordance with some embodiments, the chiplet platform 430 may further include one or more design-for-test (DFT) modules 440, one or more logic intellectual property (Logic IP) blocks 400L, and a die-to-die physical interface (D2D PHY) 450-1.

In accordance with some embodiments, the semiconductor die 300 may include a corresponding D2D PHY 450-2 configured to establish a high-speed, low-latency interconnection with the D2D PHY 450-1 of the chiplet platform 430. Through such integration, the memory access functions provided by the memory controller 400T and the memory IP block 400IP are consolidated into a single module within the chiplet platform 430, thereby simplifying the interface between the semiconductor die 300 and the chiplet platform 430.

In accordance with some embodiments, the integration of the chiplet platform 430 and the semiconductor die 300 is configured such that no PHY shift occurs between the respective die-to-die physical interfaces. In other words, the D2D PHY 450-1 of the chiplet platform 430 is directly coupled to the D2D PHY 540-2 of the semiconductor die 300 without a PHY shift. Specifically, signaling levels, data protocols, and timing domains of the chiplet platform 430 may be consistent with those of the semiconductor die 300, thereby enabling native communication across the D2D PHY.

To summarize the above, the embodiments of the present disclosure provide a semiconductor package structure in which a shortened connection path can be formed between a semiconductor die (e.g., a core die, a base die) and a memory component (e.g., a high-bandwidth memory (HBM)). For example, the vertical stacking arrangement of the semiconductor die and the memory component enables a smaller form factor compared to conventional package structures. By adopting such a configuration, the interconnect length between the semiconductor die and the memory component is significantly reduced, thereby improving electrical performance, such as lowering signal delay and enhancing power integrity. Moreover, the overall package footprint can be reduced (for example, reduced by about 1.5 to 2 reticle size), while increasing the memory bandwidth and storage (for example, increased at least by about 2-fold to 4-fold). Accordingly, the overall reliability of the semiconductor package structure can be improved.

Embodiments provide a semiconductor package structure. The semiconductor package structure includes a first substrate, a first semiconductor die, and a first memory component. The first semiconductor die is disposed over the first substrate and has a first surface adjacent to the first substrate and a second surface away from the first substrate. The first semiconductor die includes a first bonding layer disposed on the second surface of the first semiconductor die. The first memory component is disposed over the first semiconductor die. The first memory component vertically overlaps the first semiconductor die. The first memory component includes a second bonding layer adjacent to the second surface of the first semiconductor die. The first memory component is coupled to the first semiconductor die through a first connection structure formed by the first bonding layer and the second bonding layer.

In accordance with some embodiments, the first connection structure includes a hybrid bonding interface of the first bonding layer and the second bonding layer. In accordance with some embodiments, the first bonding layer includes first dielectric portions and first conductive portions. The second bonding layer includes second dielectric portions and second conductive portions. The hybrid bonding interface includes a dielectric-to-dielectric bond between the first dielectric portions and the second dielectric portions, and a metal-to-metal bond between the first conductive portions and the second conductive portions.

In accordance with some embodiments, the first memory component includes a base die and a memory die stacked over the base die.

In accordance with some embodiments, the base die includes a third bonding layer. The memory die closest to the base die includes a fourth bonding layer. The base die is coupled to the memory die through a second connection structure formed by the third bonding layer and the fourth bonding layer.

In accordance with some embodiments, the second connection structure includes a hybrid bonding interface of the third bonding layer and the fourth bonding layer.

In accordance with some embodiments, the semiconductor package structure further includes a second substrate disposed between the first substrate and the first semiconductor die. The second substrate includes a bridge structure embedded therein.

In accordance with some embodiments, the semiconductor package structure further includes a second memory component and a dielectric layer. The second memory component is disposed adjacent to the first memory component. The second memory component is disposed over the first semiconductor die. The second memory component vertically overlaps the first semiconductor die. The dielectric layer surrounds the first memory component and the second memory component.

In accordance with some embodiments, the first semiconductor die vertically overlaps the bridge structure.

In accordance with some embodiments, the semiconductor package structure further includes a third memory component and conductive connectors. The third memory component is disposed adjacent to the first semiconductor die and over the second substrate. The conductive connectors are disposed between the third memory component and the second substrate. The third memory component is coupled to the bridge structure through the conductive connectors.

In accordance with some embodiments, the semiconductor package structure further includes a bridge structure embedded in the first substrate. The first semiconductor die vertically overlaps the bridge structure.

In accordance with some embodiments, the semiconductor package structure further includes a second semiconductor die disposed over the first substrate and adjacent to the first semiconductor die. The first semiconductor die is coupled to the second semiconductor die through the bridge structure.

In accordance with some embodiments, the semiconductor package structure further includes a third memory component and conductive connectors. The third memory component is disposed adjacent to the first semiconductor die and over the first substrate. The conductive connectors 206 are disposed between the third memory component and the first substrate. The third memory component is coupled to the bridge structure through the conductive connectors.

Embodiments provide a semiconductor package structure. The semiconductor package structure includes a first substrate, a first semiconductor die, and a first memory component. The first semiconductor die is disposed over the first substrate and has a first surface adjacent to the first substrate and a second surface away from the first substrate. The first memory component includes a memory die vertically overlapping the first semiconductor die. The first semiconductor die includes first circuitry configured to control access to the first memory component.

In accordance with some embodiments, the first semiconductor die includes a first bonding layer disposed on the second surface. The memory die includes a second bonding layer adjacent to the second surface of the first semiconductor die. The first semiconductor die is coupled to the memory die through a connection structure formed by the first bonding layer and the second bonding layer.

In accordance with some embodiments, the connection structure includes a hybrid bonding interface of the first bonding layer and the second bonding layer.

In accordance with some embodiments, the semiconductor package structure further includes a second substrate disposed between the first substrate and the first semiconductor die. The second substrate includes a bridge structure embedded therein.

In accordance with some embodiments, the semiconductor package structure further includes a second memory component and a dielectric layer. The second memory component is disposed adjacent to the first memory component. The second memory component is disposed over the first semiconductor die. The second memory component vertically overlaps the first semiconductor die. The dielectric layer surrounds the first memory component and the second memory component.

In accordance with some embodiments, the semiconductor package structure further includes a bridge structure and a second semiconductor die. The bridge structure is embedded in the first substrate. The first semiconductor die vertically overlaps the bridge structure. The second semiconductor die is disposed over the first substrate and adjacent to the first semiconductor die. The first semiconductor die is coupled to the second semiconductor die through the bridge structure.

In accordance with some embodiments, the first semiconductor die includes second circuitry configured to control access within the first semiconductor die. The first circuitry is integrated into the second circuitry

In accordance with some embodiments, the first memory component further includes a base die. The memory die is stacked on the base die, and the base die is embedded in the first semiconductor die

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a first substrate;
a first semiconductor die disposed over the first substrate and having a first surface adjacent to the first substrate and a second surface away from the first substrate, and comprising a first bonding layer disposed on the second surface of the first semiconductor die; and
a first memory component disposed over and vertically overlapping the first semiconductor die, and comprising a second bonding layer adjacent to the second surface of the first semiconductor die,
wherein the first memory component is coupled to the first semiconductor die through a first connection structure formed by the first bonding layer and the second bonding layer.

2. The semiconductor package structure as claimed in claim 1, wherein the first connection structure comprises a hybrid bonding interface of the first bonding layer and the second bonding layer.

3. The semiconductor package structure as claimed in claim 2, wherein the first bonding layer comprises first dielectric portions and first conductive portions, the second bonding layer comprises second dielectric portions and second conductive portions, and the hybrid bonding interface comprises a dielectric-to-dielectric bond between the first dielectric portions and the second dielectric portions, and a metal-to-metal bond between the first conductive portions and the second conductive portions.

4. The semiconductor package structure as claimed in claim 1, wherein the first memory component comprises a base die and a memory die stacked over the base die.

5. The semiconductor package structure as claimed in claim 4, wherein the base die comprises a third bonding layer, the memory die closest to the base die comprises a fourth bonding layer, and the base die is coupled to the memory die through a second connection structure formed by the third bonding layer and the fourth bonding layer.

6. The semiconductor package structure as claimed in claim 5, wherein the second connection structure comprises a hybrid bonding interface of the third bonding layer and the fourth bonding layer.

7. The semiconductor package structure as claimed in claim 1, further comprising:
a second substrate disposed between the first substrate and the first semiconductor die, wherein the second substrate comprises a bridge structure embedded therein.

8. The semiconductor package structure as claimed in claim 7, further comprising:
a second memory component disposed adjacent to the first memory component, and disposed over and vertically overlapping the first semiconductor die; and
a dielectric layer surrounding the first memory component and the second memory component.

9. The semiconductor package structure as claimed in claim 7, wherein the first semiconductor die vertically overlaps the bridge structure.

10. The semiconductor package structure as claimed in claim 7, further comprising:
a third memory component disposed adjacent to the first semiconductor die and over the second substrate; and
conductive connectors disposed between the third memory component and the second substrate, wherein the third memory component is coupled to the bridge structure through the conductive connectors.

11. The semiconductor package structure as claimed in claim 1, further comprising:
a bridge structure embedded in the first substrate, wherein the first semiconductor die vertically overlaps the bridge structure.

12. The semiconductor package structure as claimed in claim 11, further comprising:
a second semiconductor die disposed over the first substrate and adjacent to the first semiconductor die, wherein the first semiconductor die is coupled to the second semiconductor die through the bridge structure.

13. The semiconductor package structure as claimed in claim 11, further comprising:
a third memory component disposed adjacent to the first semiconductor die and over the first substrate; and
conductive connectors disposed between the third memory component and the first substrate, wherein the third memory component is coupled to the bridge structure through the conductive connectors.

14. A semiconductor package structure, comprising:
a first substrate;
a first semiconductor die disposed over the first substrate and having a first surface adjacent to the first substrate and a second surface away from the first substrate; and
a first memory component comprising a memory die vertically overlapping the first semiconductor die,
wherein the first semiconductor die comprises first circuitry configured to control access to the first memory component.

15. The semiconductor package structure as claimed in claim 14, wherein the first semiconductor die comprises a first bonding layer disposed on the second surface, the memory die comprises a second bonding layer adjacent to the second surface of the first semiconductor die, and the first semiconductor die is coupled to the memory die through a connection structure formed by the first bonding layer and the second bonding layer.

16. The semiconductor package structure as claimed in claim 15, wherein the connection structure comprises a hybrid bonding interface of the first bonding layer and the second bonding layer.

17. The semiconductor package structure as claimed in claim 14, further comprising:
a second substrate disposed between the first substrate and the first semiconductor die, wherein the second substrate comprises a bridge structure embedded therein.

18. The semiconductor package structure as claimed in claim 17, further comprising:
a second memory component disposed adjacent to the first memory component, and disposed over and vertically overlapping the first semiconductor die; and
a dielectric layer surrounding the first memory component and the second memory component.

19. The semiconductor package structure as claimed in claim 14, further comprising:
a bridge structure embedded in the first substrate, wherein the first semiconductor die vertically overlaps the bridge structure; and
a second semiconductor die disposed over the first substrate and adjacent to the first semiconductor die, wherein the first semiconductor die is coupled to the second semiconductor die through the bridge structure.

20. The semiconductor package structure as claimed in claim 14, wherein the first semiconductor die comprises second circuitry configured to control access within the first semiconductor die, and the first circuitry is integrated into the second circuitry.

21. The semiconductor package structure as claimed in claim 14, wherein the first memory component further comprises a base die, the memory die is stacked on the base die, and the base die is embedded in the first semiconductor die.
